(19) United States
(12) Patent Application Publication
(10) Pub. No.: US 2014/0125402 A1
(43) Pub. Date: May 8, 2014

(54) SWITCHING CIRCUIT, RADIO SWITCHING CIRCUIT, AND SWITCHING METHOD THEREOF

(71) Applicant: INDUSTRIAL TECHNOLOGY RESEARCH INSTITUTE, Hsinchu (TW)

(72) Inventor: Cheng-Chung Chen, Hsinchu County (TW)

(73) Assignee: INDUSTRIAL TECHNOLOGY RESEARCH INSTITUTE, Hsinchu (TW)

(21) Appl. No.: 13/803,278

(22) Filed: Mar. 14, 2013

(30) Foreign Application Priority Data
Nov. 8, 2012 (TW) 101141631

(51) Int. Cl. H03K 17/687

(52) U.S. Cl. CPC H03K 17/687
USPC 327/427

(57) ABSTRACT

The present disclosure discloses a radio frequency switching circuit including an antenna terminal, a transmitter terminal, a receiver terminal, a first switching module, a second switching module, a first switching component, and a second switching component. The first switching module is connected between the antenna terminal and the transmitter terminal. The second switching module is connected between the antenna terminal and the receiver terminal. The first and second switching modules include several transistors respectively, and each of the transistors includes a gate terminal, a drain terminal, a source terminal, and a bulk. The first switching component has a first anode terminal connecting with the gate terminal, and a first cathode terminal connecting with the drain terminal. The second switching component has a second anode terminal connecting with the gate terminal, and a second cathode terminal connecting with the source terminal.

### CROSS-REFERENCE TO RELATED APPLICATIONS

This non-provisional application claims priority under 35 U.S.C. §119(a) on Patent Application No(s). 101141631 filed in Taiwan, R.O.C. on Nov. 8, 2012, the entire contents of which are hereby incorporated by reference.

### BACKGROUND

1. Technical Field

The present disclosure relates to a switching circuit, a radio frequency switching circuit, and a switching method thereof.

2. Related Art

In a wireless communication system, the radio frequency (RF) switch of the RF front end is a key component. In a time division duplex mode wireless system, a single-pole double-throw (SPDT) RF switch is used for switching between the two signal paths including the path between the transmitter and the antenna and the path between the antenna and the receiver. Nowadays, in a multi-frequency multi-module wireless system, the SPDT RF switch between several RF front-end modules is also adopted.

FIG. 1 shows a structure of a conventional RF switch 1. The serially connected transistors Q1 and Q2 are used for controlling two signal paths, and the parallel connected transistors Q3 and Q4 are for ensuring the isolation. The gate terminal of each of the transistors Q1-Q4 is connected to a resistor R. One important linearity specification of a RF switch is its maximum power handling capability, i.e., the maximum input power from the transmitter (TX) terminal that leads to no distortion beyond a specified system regulation at the Antenna (Ant) terminal. In the case of the TX mode of a RF switch circuit, i.e., the circuit is switched to the signal path between the TX terminal and the ANT terminal, the control voltage unit 10 may turn on the transistors Q2 and Q3 and turn off the transistors Q1 and Q4. In the wireless communication system, at the typical TX output power level ranging from half watts to several watts, the transistors Q1 and Q4 must be able to remain in their turned-off state to prevent an unintentional signal path switch, which may destroy the linearity of the RF switch, from taking place. The conventional solution for preventing the transistors from being turned on by the high power RF signal is to stack two or more transistors to reduce the signal voltage distribution on each junction of the transistors. For example, the pair of serially connected transistors Q5 and Q6 as shown in FIG. 2A can replace Q1 and Q4, respectively, to enhance the RF power handling by 6 dB. FIG. 2B shows a transistor with a dual-gate structure Q7 including a drain terminal, a source terminal, and two gate terminals. The multi-gate transistors such as transistor Q7 that could be implemented in the standard manufacturing processes of gallium arsenide (GaAs) may be associated with the power handling functionalities thereof similar to the stack structure in FIG. 2A. Another conventional method for increasing the power handling of the turned-off transistors in the RF switch is the employment of feed forward capacitors on stacked transistors or multi-gate transistor as shown in FIG. 2A and FIG. 2B. The two feed forward capacitors, which have low impedance at their operating frequency, prevent the conduction of the underlying gate-drain or gate-source channel during a certain portion of an RF cycle. Therefore, the linearity of RF switch could further be increased by the improved RF power handling of turned-off transistors.

Manufacturing an RF switch in the CMOS manufacturing process is much more challenging than its GaAs counterpart. Because of the parasitic nature and characteristics of the CMOS substrate, the low breakdown voltage performance of a CMOS transistor tends to limit the high power application of CMOS RF switch circuits. However, to reduce costs and improve the system integration, a continuing design problem is the manufacturing of a high power RF switch using the standard CMOS manufacturing process. Since multi-gate transistors are unavailable in the standard CMOS process, FIG. 2C shows the proposed solution for realizing a high power CMOS RF switch, which is to stack up to three or four transistors with feed forward capacitors on the first and last transistor. While in their turned off state, three stacked transistors Q8, Q9 and Q10 theoretically could provide 9.5 db more the RF power handling capability than the single transistor Q1 or Q4. Moreover, the feed-forward capacitors Q5 and Q6 could increase several dBs in the maximum operating power. However, the utilizing of feed-forward capacitors over the stacked transistor circuit may be subject to long term reliability issue due to un-uniformed voltage distribution at each gate-drain or gate-source junction. The un-uniformed distribution may result in relatively large voltage stress at certain portions of one RF cycle at one junction. Such large voltage stress may become more problematic as the input power into a RF switch approaches its maximum rating power. Therefore, the maximum operating power of the RF switch must be decreased to improve reliability. This could, however, offset the advantage of the feed forward capacitor usage to some extent.

### SUMMARY

The present disclosure provides a switching circuit, a radio frequency (RF) switching circuit, and a switching method thereof. The present disclosure relies on the switching of paths for protecting the transistors in the switching circuits from being turned on by the alternating-current (AC) signals.

A switching circuit is disclosed according to an embodiment of the present disclosure. The switching circuit includes a transistor, a first switching component, and a second switching component. The transistor includes a gate terminal, a drain terminal, a source terminal, and a bulk. A passivation layer is formed on a surface of a substrate. The first switching component has a first anode terminal and a first cathode terminal. The first anode terminal is connected with the gate terminal, and the first cathode terminal is connected with the drain terminal. The second switching component has a second anode terminal and a second cathode terminal. The second anode terminal is connected with the gate terminal, and the second cathode terminal is connected with the source terminal.

An RF switching circuit is disclosed according to an embodiment of the present disclosure. The RF switching circuit includes an antenna terminal, a transmitter terminal, a receiver terminal, a first switching module, and a second switching module. The first switching module is connected between the antenna terminal and the transmitter terminal. The second switching module is connected between the antenna terminal and the receiver terminal. The first switching module has several serially connected switching circuits. The switching circuit includes a transistor, a first switching component, and a second switching component. The transistor has a gate terminal, a drain terminal, a source terminal, and a bulk. A passivation layer is formed on a surface of a substrate. The first switching component has a first anode terminal and a first cathode terminal. The first anode terminal is connected with the gate terminal, and the first cathode terminal is connected with the drain terminal. The second switching component has a second anode terminal and a second cathode terminal. The second anode terminal is connected with the gate terminal, and the second cathode terminal is connected with the source terminal.

A switching method of turned-off RF switching circuit that is capable of enhancing the capability of the power handling is disclosed according to an embodiment of the present disclosure. The method includes a step of providing a first switching path which is electrically connected between a gate terminal and a drain terminal of a transistor. The method also includes a step of providing a second switching path which is electrically connected between the gate terminal and a source terminal of the transistor. The method also includes a step of providing an AC signal associated with a positive period part and a negative period part introduced at the drain terminal. The second switching path is turned on responding to the AC RF signal in the positive period, and the first switching path is considered as high impedance responding to the AC signal in the positive period. The first switching path is turned on responding to the AC signal in the negative period, and the second switching path may be considered as high impedance responding to the AC signal in the negative period.

According to the RF switching circuit of the present disclosure, feed-forward capacitors are disclosed and incorporated to be with each serially connected transistor. When the RF switching circuit operates at high power ranges, each serially connected transistor may averagely share the AC voltages of the signals and remain in the turned-off state, therefore increasing the operation power and reliabilities of the circuits. In addition, the RF switching circuit of the present disclosure may be implemented in standard manufacturing processes of a complementary metal-oxide semiconductor (CMOS). The circuit uses two switching components for protecting the transistors from being turned on by the AC signals, in order to improve the reliability of the structure of the conventional feed-forward capacitors.

The embodiments of the features and implementations of the present disclosure are described as follows along with some figures.

### BRIEF DESCRIPTION OF THE DRAWINGS

The present disclosure will become more fully understood from the detailed description given herein below for illustration only, and thus are not limitative of the present disclosure, and wherein:

FIG. 1 shows a circuit diagram of a conventional radio frequency switcher according to the conventional techniques;

FIG. 2A shows a circuit diagram of a transistor serial connection structure according to the conventional techniques;

FIG. 2B shows a circuit diagram of a multi-gate transistor structure according to the conventional techniques;

FIG. 2C shows a circuit diagram of a standard complementary metal-oxide semiconductor manufacturing process for designing a radio frequency switch according to the conventional techniques;

FIG. 3 shows a circuit diagram of a switching circuit according to the present disclosure;

FIG. 4 shows a waveform diagram of circuit signals according to the present disclosure;

FIG. 5 shows a circuit diagram of a transistor switching circuit which is a diode connected transistor according to the present disclosure;

FIG. 6 shows a circuit diagram of a parasitic diode switching circuit of a transistor bulk according to the present disclosure;

FIG. 7 shows a circuit diagram of a radio frequency switching circuit according to the present disclosure;

FIG. 8 shows a circuit diagram of a radio frequency switching circuit according to another embodiment of the present disclosure; and

FIG. 9 shows a flow chart of a switching method of a radio frequency switching circuit according to the present disclosure.

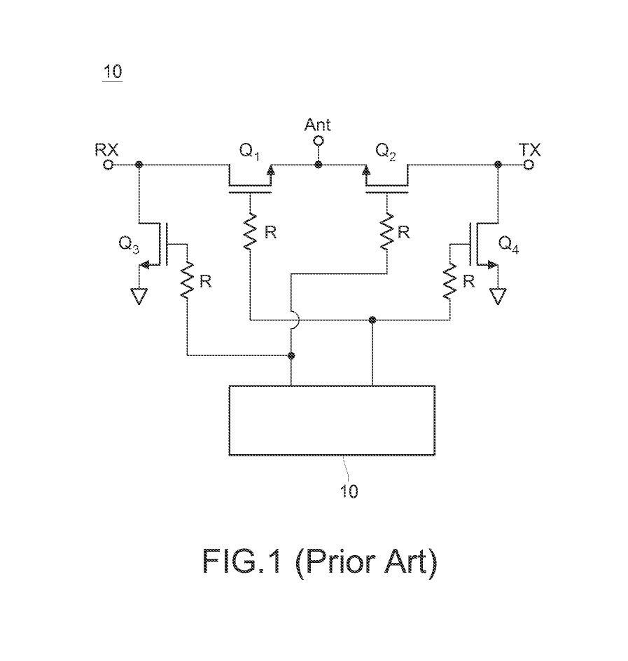

### DETAILED DESCRIPTION

The embodiments described below show the detail features and advantages of the present disclosure. The content thereof may be enough to the one skilled in the art to understand the techniques and implement the contents accordingly. The following embodiments further show the view points of the present disclosure, but are not for limiting the scope of the present disclosure.

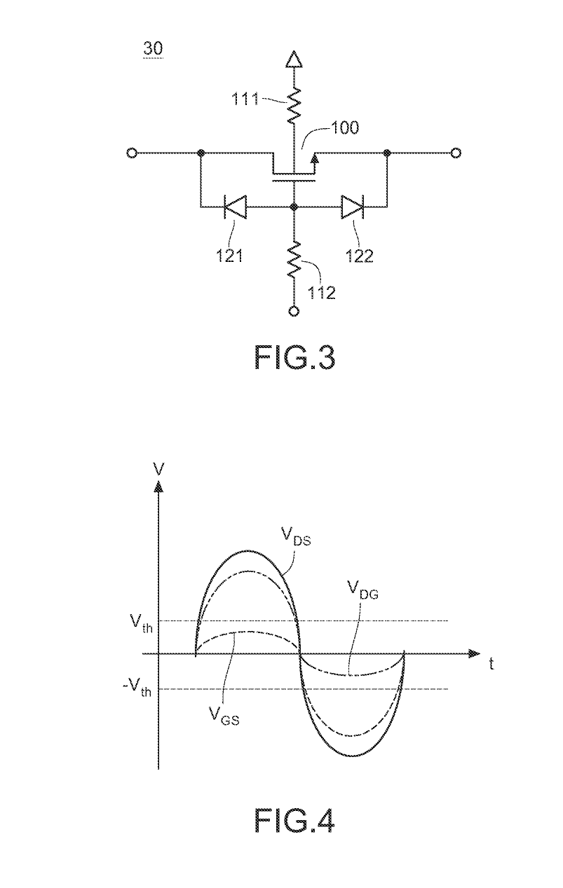

Please refer to FIG. 3 which shows a circuit diagram of a switching circuit 30. The switching circuit 30 includes a transistor 100, a first switching component 121, a second switching component 122, a first resistor 111, and a second resistor 112.

As shown in figure, the transistor 100 includes a gate terminal, a drain terminal, a source terminal, and a bulk. The first switching component 121 has a first anode terminal and a first cathode terminal. The first anode terminal is connected to the gate terminal, and the first cathode terminal is connected to the drain terminal. The second switching component 122 has a second anode terminal and a second cathode terminal. The second anode terminal is connected to the gate terminal, and the second cathode terminal is connected to the source terminal. In addition, the first resistor 111 in the switching circuit 30 is connected between the bulk of the transistor 100 and a system ground terminal, which effectively causes the high impedance at the bulk in the operating frequency. The gate terminal of the transistor 100 is connected to the second resistor 112, and to the control voltage through the second resistor 112.

The switching circuit 30, which is able to handle relatively large RF signals in its turned-off state, is usually disposed as the serially connected circuit between the antenna terminal and the receiver terminal of the RF switching circuits, or the shunt circuit between the transmitter terminal and the system ground terminal. The present disclosure connects one first switching component 121 and one second switching component 122 respectively between the gate terminal and drain terminal of the transistor 100 and between the gate terminal and source terminal of the transistor 100. The first switching component 121 and the second switching component 122 serve as a common-anode diode pair with the anode terminals of the two components connected together. The common-anode diode pair is for restricting the superimposed voltage between the gate terminal and the drain terminal/source terminal, by respectively having each of the switching components conducted in accordance with the positive and negative periods of the RF signals between the drain terminal and the source terminal of the transistor, in order to prevent the transistor from being turned on by the large AC signals.

As shown in FIG. 4, a sinusoidal waveform diagram is illustrated as an example for explaining the switching method of an RF switching circuit according to one embodiment of the present disclosure. The first switching component 121 provides a first switching path, and the second switching component 122 provides a second switching path. When the transistor 100 is turned-off in the RF switching circuits, the waveform V_{DS} passes through the drain terminal, the superimposed AC voltage between the drain terminal and the gate terminal of the transistor 100 is V_{BG}, and the superimposed AC voltage between the gate terminal and the source terminal is V_{GS}. During the positive period of the signal waveform, the second switching path of the second switching component 122 may be conducted by the forward biasing, and the first switching path of the first switching component 121 may be associated with a high impedance as the result of the reverse biasing. Thus, the superimposed voltage between the gate terminal and the source terminal may be suppressed to be smaller than the conduction voltage Vₜₕ of the transistor. On the other hand, the similar mechanism applies during the negative period of the signal waveform. This mechanism may obviously improve the problem of the transistor 100 being conducted under larger AC signals, and further increase the linear operation power of the RF switching circuit. The efficacy generated by the circuits is similar to the conventional feed-forward techniques implemented in terms of several serially connected transistors, when the benefits of the circuits disclosed by the present disclosure may be realized in one single transistor.

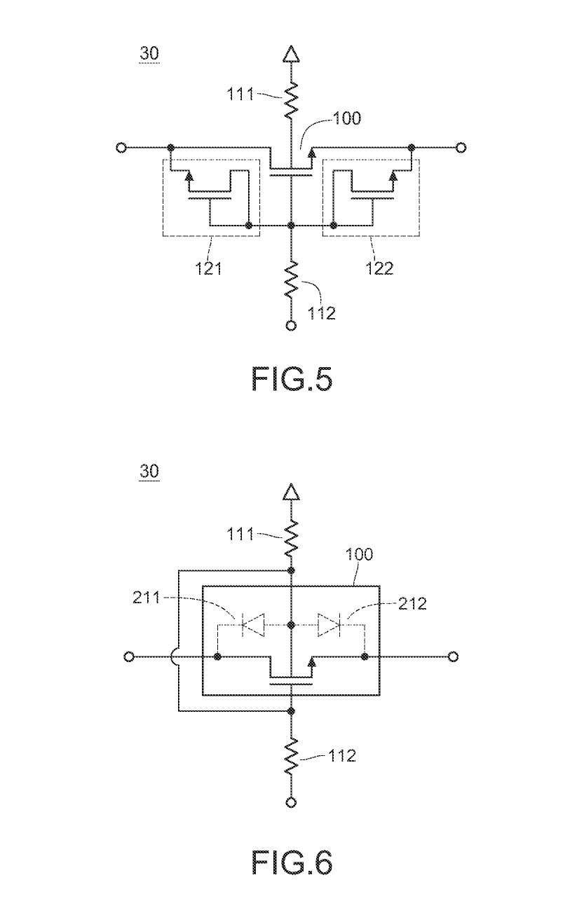

Please refer to FIG. 5, wherein the first switching component 121 and/or the second switching component 122 is a diode connected transistor. FIG. 5 shows an implementation structure of FIG. 3 implemented in CMOS manufacturing processes. That is, the diodes in FIG. 3 are implemented by the diode connected transistors. The equivalent impedances of the diode connected transistors is variable within a large range of superimposed voltages, thus are suitable for implementing the structure provided in this disclosure.

Please refer to FIG. 6, wherein the first switching component 121 and/or the second switching component 122 could be a parasitic diode between the bulk and the source terminal or the drain terminal of the transistor. FIG. 6 shows another implementation for the structure of FIG. 3. The bulk and the gate terminal of the transistor are connected with each other when the transistor is in its turned-off state. A first parasitic diode 211 and a second parasitic diode 212 inherent in the bulk of the transistor 100 are used for replacing the first switching component 121 and/or the second switching component 122, and may also be used for restricting the superimposed voltage between the gate terminal and the source terminal/drain terminal at the time the first parasitic diode 211 and the second parasitic diode are conducted, in order to protect the transistor from being turned on by the large AC signals.

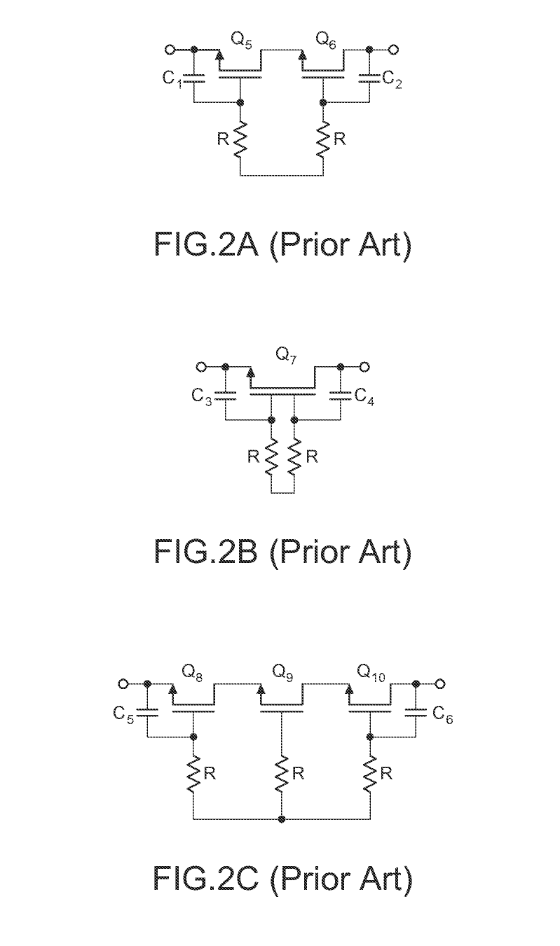

In addition to increasing the operation power of one single transistor when it is turned off, when the switching circuit needs to operate at larger power ranges, such as the power ranges of more than one watt, the present disclosure may also be applied in the structure with several serially connected transistors (e.g., stacked transistors). When the present disclosure is applied in the structure with several serially connected transistors, the operation power and the circuit reliability improve comparing to the conventional structure of the feed-forward capacitor along with several serially connected transistors or the structure having the several serially connected transistors only. Taking the structure of two serially connected transistors for example, when the both serially connected transistors are in their turned-off states, and driven by a power sweeping sinusoidal signal, a defined linear operating power and the superimposed voltage between the specified electrodes of transistors are simulated and compared as follows. FIG. 2A shows one example circuit without two capacitors C1 and C2 when including two 3.3 volts serially connected CMOS n-type FET transistors. The length of the gate of the transistor is 0.35 μm, and the total width of the gate is 480 μm. The example circuit includes a sinusoidal input terminal that is fifty Ohms in impedance, an output terminal that is also fifty Ohms in impedance, and the pair of serially connected transistors, which are turned-off by with zero volt bias. The input terminal is connected directly to the output terminal. The transistor pair is in the shunted connection with the drain of the transistor Q6 connected to the input terminal and the source of the transistor Q5 connected to the system ground. The simulation results show that when the frequency is 2.4 GHz and the input power of the sinusoidal signal is increased to 23.8 dBm, the channels of the two transistors start to conduct and therefore cause 0.5 dB extra insertion loss comparing with that associated with the input of small signals. That is the defined maximum linear operating power, Pin 0.5 dB=23.8 dBm. In the second example circuit where the first feed-forward capacitor C1=0.5 pF and the second feed-forward capacitor C2=0.5 pF are added as shown is FIG. 2A, the Pin 0.5 dB thereof may increase to 30 dBm. It is worth noting that when the input power is 30 dBm, the drain terminal and the gate terminal of the transistor Q5 may endure most of the superimposed voltage during the positive half period of the AC signal, with the endured voltage up to 6 volts. Similarly, during the negative half-period of the AC signal, the source terminal and the gate terminal of the transistor Q6 may endure most of the superimposed voltage. This may cause reliability problem of the RF switching circuit, especially the ones that is produced by the CMOS manufacturing processes. In another example circuit shown in FIG. 5, two switching circuits are used to replace the transistors Q5 and Q6. And the transistor 100 may be considered equivalent to the transistors Q5 and Q6 in the previous two examples and the additionally added diode connected transistors are 3.3 volt N-type MOS FET transistors having the gate length in 0.35 μm and gate total width in 80 μm. The simulation results show that the circuits according to the present disclosure may still increase the operation power Pin0.5 dB to 30 dBm. Because the diode connected transistors operate at the same time, the superimposed voltages of the two transistors are almost equally distributed. Thus, over the positive or negative period of the 30 dBm input signal, the maximum voltages between the gate terminal and the drain terminal or the source terminal of the two transistors are decreased to 3.6 Volts, which is relatively smaller comparing with their counterparts in FIG. 2A. Consequently, it is believed the reliability of the transistors may improve when the present disclosure is incorporated in the operations associated with relatively large powers. In another example where the parasitic diodes of the transistors are used as described in FIG. 6, the operating power Pin0.5 dB is further increased to 36.8 dBm. It is noted in this case, with the same 30 dBm signal power, the maximum voltages between the gate terminal and the source terminal or the drain terminal of the transistor are 4.7 volts, which is also smaller than their counterparts in FIG. 2A.

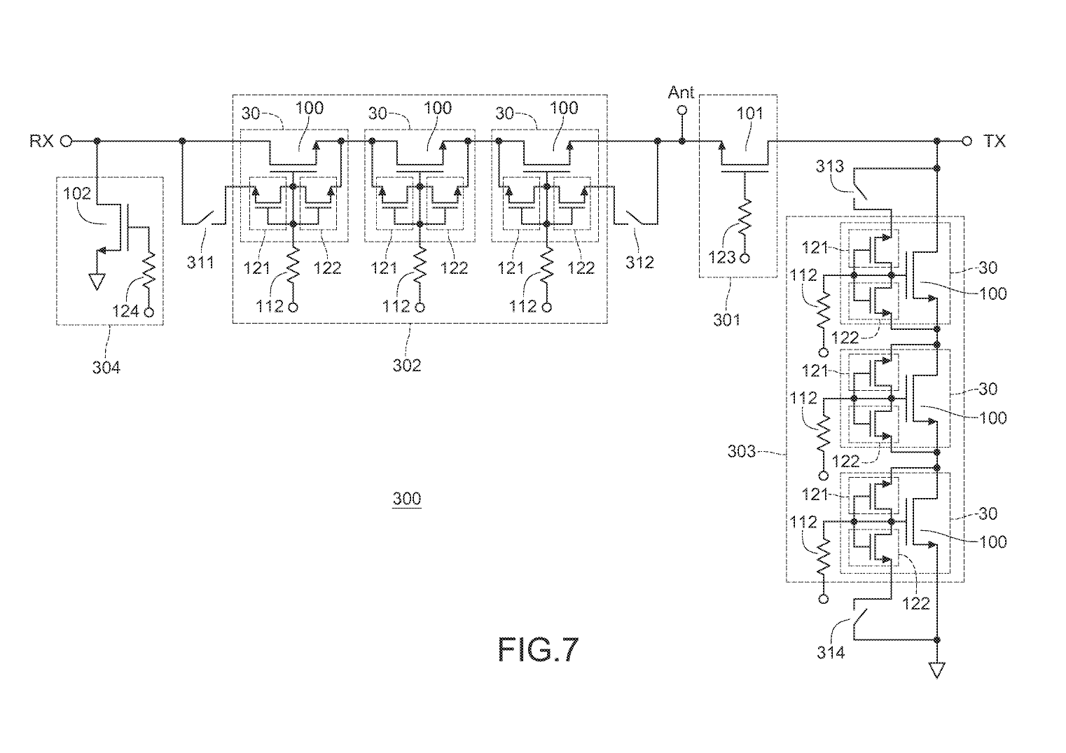

Please refer to FIG. 7 which is a circuit diagram of an RF switching circuit 300 of the switching circuit according to one embodiment of the present disclosure. The RF switching circuit 300 includes an antenna terminal Ant, a transmitter terminal TX, a receiver terminal RX, a first switching module 301, a second switching module 302, a third switching module 303, and a fourth switching module 304.

The first switching module 301 includes a first transistor 101, and the fourth switching module 304 includes a second transistor 102. The first transistor 101 is connected to a voltage control unit through a third resistor 123, and the second transistor 102 is connected to the voltage control unit through a fourth resistor 124.

The second switching module 302 and the third switching module 303 may be implemented in the form of several of the switching circuits described in the above embodiments. The switching circuits in the second switching module 302 and the switching circuits in the third switching module 303 are serially connected. The second switching module 302 and the third switching module 303 respectively include several transistors 100, several first switching components 121, and several second switching components 122. Each transistor 100 has a gate terminal, a drain terminal, a source terminal, and a bulk. Each first switching component 121 includes a first anode terminal and a first cathode terminal, wherein the first anode terminal is connected with the gate terminal, and the first cathode terminal is connected with the drain terminal. Each second switching component 122 has a second anode terminal and a second cathode terminal, wherein the second anode terminal is connected with the gate terminal and the second cathode terminal is connected with the source terminal. The first switching component 121 and/or the second switching component 122 may be a diode, a diode connected transistor or a parasitic diode of the bulk of the transistor.

Please refer to FIG. 7 again for the illustration of the circuit structure embodiment of the RF switching circuit 300 according to one embodiment of the present disclosure, which implements the path switching of the antenna terminal Ant and the transmitter terminal TX and the receiver terminal RX. For improving the power endurance when the path between the transmitter terminal TX and the antenna terminal Ant is conducted, the transistor 100 is arranged to be connected between the antenna terminal Ant and the receiver terminal RX, or between the transmitter terminal TX and a system ground terminal. For further satisfying the need of increased operation power and the reliability, the serially connected transistors 100 are all installed along with the first switching component 121 and the second switching component 122. And the serially connected transistors 100 in such arrangement may effectively function as diode connection transistors shown in FIG. 5. In addition, a first switch circuit 311, a second switch circuit 312, a third switch circuit 313, and a fourth switch circuit 314 may become necessary in one implementation. The first switch circuit 311 is connected between the second switching module 302 and the receiver terminal RX, the second switch circuit 312 is connected between the second switching module 302 and the antenna terminal Ant, the third switch circuit 313 is connected between the third switching module 303 and the transmitter TX, and the fourth switch circuit 314 is connected between the fourth switching module 304 and the ground terminal. Accordingly, the control voltages that turn on the serially connected transistors 100 may be prevented from being fed into the system ground through the diodes when the antenna terminal Ant is switched to the receiver terminal RX.

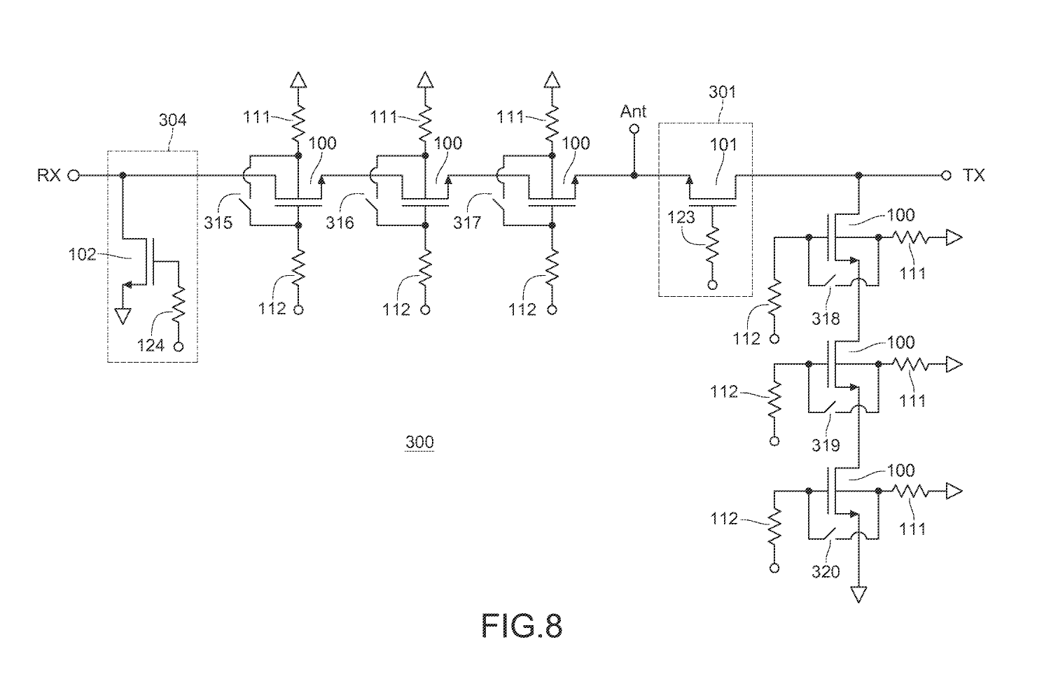

Please refer to FIG. 8 for illustrating another circuit structure embodiment of the RF switching circuit 300 according to another embodiment of the present disclosure, which implements the path switching between an antenna terminal Ant and a transmitter terminal TX and a receiver terminal RX. The same symbols in this embodiment represent the same components in the above embodiments. For the purpose of more/larger power endurance when the path between the transmitter terminal TX and the antenna terminal Ant is turned on, the transistors 100 are serially connected between the antenna terminal Ant and the receiver terminal RX, or between the transmitter terminal TX and a system ground terminal. For further satisfying the need of increased operation power and the reliability, the serially connected transistors 100 connect the gate terminals and the bulks thereof together as shown in FIG. 6. The first parasitic diode 211 and a second parasitic diode 212 between the bulk and drain/source terminals are used for replacing the externally added first switching component 121 and/or the second switching component 122. For simplifying the figure, the parasitic diodes are not depicted in the figures. In addition, the circuit may externally add a fifth switch circuit 315, a sixth switch circuit 316, a seventh switch circuit 317, an eighth switch circuit 318, a ninth switch circuit 319, and a tenth switch circuit 320, wherein each of the switch circuits 315-320 is disposed between the bulk and the gate terminal. That is, each switch circuit is correspondingly connected between the anode terminals of the first and second switching components which are not shown in this figure, and the gate terminal of the corresponding transistor 100. The connections are for avoiding the control voltages that could turn on the serially connected transistors 100 from being fed into the system ground through the diodes when the antenna terminal Ant is switched to the receiver terminal RX.

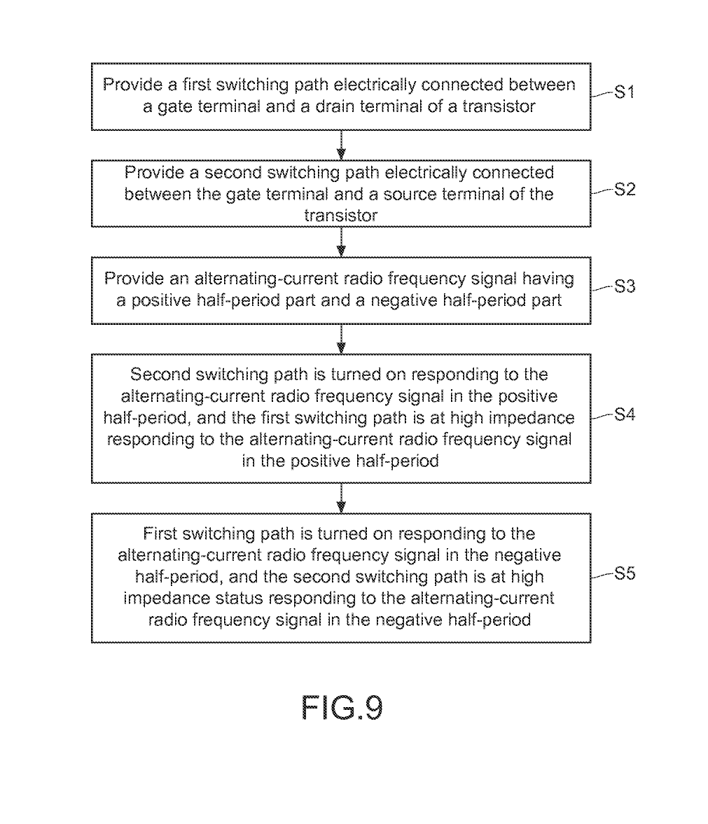

Please refer to FIG. 9 which is a flow chart of a switching method of a turned-off RF switching circuit according to an embodiment of the present disclosure. The switching disclosed includes a step of providing a first switching path, wherein the first switching path is electrically connected between a gate terminal and a drain terminal of a transistor (step S1). The method further includes a step of providing a second switching path, wherein the second switching path is electrically connected between the gate terminal and a source terminal of the transistor (step S2). The method further includes a step of providing an AC signal having a positive period part waveform and a negative period part waveform (step S3) at the drain terminal. The second switching path is turned on responding to the AC signals in the positive periods, and the first switching path may be considered as high impedance responding to the AC signals in the positive periods (step S4). The first switching path is turned on responding to the AC signals in the negative periods, and the second switching path may be considered as high impedance responding to the AC signals in the negative periods (step S5).

According to the RF switching circuits of the present disclosure, a new implementation of the feed-forward capacitors is provided, and it is designed in each serially connected transistor. When the RF switching circuits are working at high power ranges, each of the serially connected transistors in its turned-off state averagely shares the AC voltages of the signals, for obviously increasing the workable operation power and reliability of the circuits.

What is claimed is:

1. A switching circuit comprising:
a transistor including a gate terminal, a drain terminal, a source terminal, and a bulk;
a first switching component having a first anode terminal and a first cathode terminal, wherein the first anode terminal is connected with the gate terminal, and the first cathode terminal is connected with the drain terminal; and
a second switching component having a second anode terminal and a second cathode terminal, wherein the second anode terminal is connected with the gate terminal, and the second cathode terminal is connected with the source terminal.

2. The switching circuit according to claim 1, further comprising a first resistor, wherein the first resistor is connected between the bulk of the transistor and a system ground terminal.

3. The switching circuit according to claim 1, further comprising a second resistor electrically connected to the gate terminal of the transistor.

4. The switching circuit according to claim 1, wherein the first switching component and/or the second switching component is a diode connected transistor.

5. The switching circuit according to claim 1, wherein the first switching component and/or the second switching component is a parasitic diode between the bulk and the source terminal or the drain terminal of the transistor, and the first anode terminal of the first switching component and the second anode of the second switching component and the gate terminal are connected through a switch circuit.

6. A radio frequency switching circuit comprising:
an antenna terminal;
a transmitter terminal;
a receiver terminal;
a first switching module connected between the antenna terminal and the transmitter terminal; and
a second switching module connected between the antenna terminal and the receiver terminal;
wherein the second switching module includes a plurality of switching modules, and each of the switching modules has:
a transistor including a gate terminal, a drain terminal, a source terminal, and a bulk;
a first switching component having a first anode terminal and a first cathode terminal, wherein the first anode terminal is connected with the gate terminal, and the first cathode terminal is connected with the drain terminal; and
a second switching component having a second anode terminal and a second cathode terminal, wherein the second anode terminal is connected with the gate terminal, and the second cathode terminal is connected with the source terminal.

7. The radio frequency switching circuit according to claim 6, further comprising a plurality of first resistors, wherein each of the first resistors is correspondingly connected between the bulk of each of the transistors and a system ground terminal.

8. The radio frequency switching circuit according to claim 6, further comprising a plurality of second resistors, wherein each of the second resistors is correspondingly connected with the gate terminal of each of the transistors.

9. The radio frequency switching circuit according to claim 6, wherein the first switching component and/or the second switching component is a diode connected transistor.

10. The radio frequency switching circuit according to claim 6, wherein the first switching component and/or the second switching component is a parasitic diode between the bulk and the source terminal or the drain terminal of the transistor.

11. The radio frequency switching circuit according to claim 10, further comprising a switch circuit electrically connected between the first anode terminal of the first switching component and the second anode terminal of the second switching component and the gate terminal of the transistor.

12. The radio frequency switching circuit according to claim 6, wherein the first switching module includes a first transistor.

13. The radio frequency switching circuit according to claim 7, further comprising a third switching module connected between the transmitter terminal and the system ground terminal, wherein the third switching module includes a plurality of switching modules in the second switching module.

14. The radio frequency switching circuit according to claim 7, further comprising a fourth switching module connected between the receiver terminal and the system ground terminal, wherein the fourth switching module includes a second transistor.

15. The radio frequency switching circuit according to claim 7, further comprising a first switch circuit, a second switch circuit, a third switch circuit, and a fourth switch circuit, wherein the first switch circuit is connected between the second switching module and the receiver terminal, the second switch circuit is connected between the second switching module and the antenna terminal, the third switch circuit is connected between a third switching module and the transmitter terminal, and the fourth switch circuit is connected between a fourth switching module and the system ground terminal.

16. A switching method of a radio frequency switching circuit, comprising:
providing a first switching path, wherein the first switching path is electrically connected between a gate terminal and a drain terminal of a transistor;
providing a second switching path, wherein the second switching path is electrically connected between the gate terminal and a source terminal of the transistor;
providing an alternating-current radio frequency signal, wherein the alternating-current radio frequency signal is defined by a positive period part waveform and a negative period part waveform;
the second switching path turning on responding to the positive period part waveform of the alternating-current radio frequency signal, the first switching path becoming a high impedance status responding to the positive period part waveform of the alternating-current radio frequency signal; and
the first switching path being conducted responding to the negative period part waveform of the alternating current radio frequency signal, the second switching path considered as a high impedance responding to the negative period part waveform of the alternating-current radio frequency signal.
